(19) United States
(12) Patent Application Publication
(10) Pub. No.: US 2026/0293184 A1
(43) Pub. Date: Sep. 24, 2026

(54) HIGH ELECTRON MOBILITY TRANSISTOR, RF SWITCH CIRCUIT, POWER AMPLIFIER CIRCUIT, AND WIRELESS COMMUNICATION TERMINAL

(71) Applicant: Sony Semiconductor Solutions Corporation, Kanagawa (JP)

(72) Inventor: Kazuki Kishida, Tokyo (JP)

(21) Appl. No.: 19/490,145

(22) PCT Filed: May 15, 2024
(86) PCT No.: PCT/JP2024/017894

§ 371 Date: Dec. 4, 2025

(30) Foreign Application Priority Data
Jun. 28, 2023 (JP) 2023-106351

(51) Int. Cl. H10D 30/47; H10D 30/01; H10D 64/27; H10D 64/68

(52) U.S. Cl. CPC H10D 30/476; H10D 30/015; H10D 30/475; H10D 64/514; H10D 64/685

(57) ABSTRACT

A high electron mobility transistor and related devices are disclosed. In one example, a high electron mobility transistor includes a semiconductor layer, a gate electrode, and a gate insulating film between the semiconductor layer and the gate electrode. The gate insulating film includes a first insulating film in contact with the semiconductor layer and a second insulating film in contact with the first insulating film and the gate electrode.

### TECHNICAL FIELD

The present technology relates to a high electron mobility transistor, an RF switch circuit, a power amplifier circuit, and a wireless communication terminal.

### BACKGROUND ART

A high electron mobility transistor of a nitride semiconductor has a wide band gap as well as an extremely large dielectric breakdown voltage and saturated electron velocity, and thus has attracted attention for increasing an output and speed of electronic devices (see, for example, PTL 1).

### CITATION LIST

### Patent Literature

PTL 1: Japanese Unexamined Patent Application Publication No. 2009-302435

### SUMMARY OF THE INVENTION

Incidentally, there is a demand for further enhancement of an operating property of a high electron mobility transistor of a nitride semiconductor. Accordingly, it is desirable to provide a high electron mobility transistor that makes it possible to further enhance an operating property, and an RF switch circuit, a power amplifier circuit, and a wireless communication terminal each including such a high electron mobility transistor.

A high electron mobility transistor according to an embodiment of the present technology includes: a semiconductor layer; a gate electrode; and a gate insulating film provided between the semiconductor layer and the gate electrode. The gate insulating film includes: a first insulating film in contact with the semiconductor layer; and a second insulating film in contact with the first insulating film and the gate electrode. The first insulating film and the second insulating film satisfy relational expressions (A), (B), and (C) below.

$$EOT ( T 1 ) / EOT ( T 2 ) \geq 1.43 \qquad ( A )$$

$$EOT ( T 2 ) \leq 0.75 nm \qquad ( B )$$

$$ε 1 \geq ε 2 \qquad ( C )$$

where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance

An RF switch circuit according to an embodiment of the present technology includes the above-described high electron mobility transistor.

A power amplifier circuit according to an embodiment of the present technology includes the above-described high electron mobility transistor.

A wireless communication terminal according to an embodiment of the present technology includes the above-described high electron mobility transistor.

### BRIEF DESCRIPTION OF THE DRAWINGS

FIG. 1 is a diagram illustrating a cross-sectional configuration example of a high electron mobility transistor according to an embodiment of the present technology.

FIG. 2 is a diagram illustrating a planar configuration example of the high electron mobility transistor of FIG. 1.

FIG. 3 is a graph illustrating an example of an energy band of the high electron mobility transistor of a comparative example.

FIG. 4 is a graph illustrating an example of an energy band of high electron mobility transistors of examples illustrated in FIG. 1.

FIG. 5 is a graph illustrating an example of a threshold voltage variation when stress is applied to the high electron mobility transistors of the examples and the high electron mobility transistor of the comparative example.

FIG. 6 is a graph illustrating conditions for a gate insulating film of FIG. 1.

FIG. 7A is an explanatory diagram of a manufacturing step of the high electron mobility transistor of FIG. 1.

FIG. 7B is an explanatory diagram of a manufacturing step subsequent to FIG. 7A.

FIG. 7C is an explanatory diagram of a manufacturing step subsequent to FIG. 7B.

FIG. 7D is an explanatory diagram of a manufacturing step subsequent to FIG. 7C.

FIG. 8 is a diagram illustrating a modification example of the cross-sectional configuration of the high electron mobility transistor of FIG. 1.

FIG. 9 is a diagram illustrating a modification example of the cross-sectional configuration of the high electron mobility transistor of FIG. 1.

FIG. 10 is a diagram illustrating a circuit configuration example of an RF switch circuit.

FIG. 11 is a diagram illustrating a circuit configuration example of a wireless communication apparatus.

FIG. 12 is a diagram illustrating a circuit configuration example of a power amplifier module.

### MODES FOR CARRYING OUT THE INVENTION

Hereinbelow, detailed description is given of an embodiment of the present technology with reference to the drawings.

### 1. BACKGROUND

The fifth-generation mobile communication (5G) uses electric waves in a high frequency band. Such electric waves involve large propagation loss, making it necessary to transmit the electric waves at high electric power. Accordingly, there is a demand for a device, particularly in a mobile terminal, that achieves high output, high efficiency, and excellent heat resistance.

A GaN material that is a type of a group III-V semiconductor features high withstand voltage, high heat resistance, and high saturated drift velocity. In a high electron mobility transistor (HEMT) including a GaN material, two-dimensional electron gas (2DEG) is formed at a heterojunction. This 2DEG has high mobility and high sheet electron density. With these features, a GaN HEMT is operable at low resistance, high speed, and high withstand voltage, and is thus expected as a high-frequency device for a 5G terminal.

In terms of a gate structure, the GaN HEMT is roughly classified into: a Schottky type in which a Schottky junction is formed between gate metal and a semiconductor layer; and an MIS structure type in which gate metal and a semiconductor layer are bonded to each other with an insulating film provided therebetween. Of these, the MIS type HEMT including the insulating film between a semiconductor and the gate metal enables suppression of a gate leakage in off operation and a reduction in power consumption. Accordingly, the MIS type HEMT is suitable for use in a mobile terminal.

Meanwhile, a device for a mobile terminal has a constraint on a circuit scale, specifically has no area in which a feedback circuit that compensates for a threshold voltage variation is to be mounted. It is thus highly important that no threshold voltage variation occurs during operation of the device. In the MIS type HEMT, presence of a gate insulating film generates an interface state at an interface between the gate insulating film and the semiconductor layer. This causes an issue that the threshold voltage variation occurs when electric charge is injected from the gate metal into the interface state and trapped in the interface state during the operation of the device. Further, if a film thickness of the gate insulating film is increased to reduce the injection of the electric charge into the interface between the gate insulating film and the semiconductor layer, a gain of the transistor decreases. Accordingly, in the MIS type HEMT, the suppression of the threshold voltage variation and the enhancement of the gain are in a tradeoff relationship.

To solve this problem and achieve the suppression of the threshold voltage variation and the enhancement of the gain, PTL 1 discloses a technique of suppressing the variation by configuring an insulating film to include two or more layers.

In an invention described in PTL 1 described above, it is expected that configuring the insulating film to include two or more layers reduces injection of electric charge from gate metal into an interface between a gate insulating film and a semiconductor layer to thereby suppress the threshold voltage variation. This invention, however, still has the following issues.

In the invention described in PTL 1 described above, the gate insulating film includes: a first insulating film in contact with a semiconductor; and a second insulating film stacked on the first insulating film. In terms of the threshold voltage variation, it is necessary to consider an influence, on a threshold voltage, of trapping not only at the interface between the gate insulating film and the semiconductor layer but also in an interface state generated at an interface between the first insulating film and the second insulating film. That is, it is necessary to consider an influence, on the threshold voltage variation, of the electric charge injected into the interface between the first insulating film and the second insulating film.

In the invention described in PTL 1 described above, a film thickness of the second insulating film is defined as 2 nm or greater. Such a film thickness, however, makes it unable to achieve an adequate effect of suppressing the threshold voltage variation due to the influence of the electric charge injected into the interface between the first insulating film and the second insulating film. Further, in the invention described in PTL 1 described above, thinning of the gate insulating film is insufficient, resulting in a decrease in a gain of a transistor. The inventor of the present application has conceived of the following configuration after intensively studying a configuration that makes it possible to achieve both the suppression of the threshold voltage variation and the enhancement of the gain. Hereinbelow, detailed description is given of the configuration.

### 2. EMBODIMENT

### <Configuration>

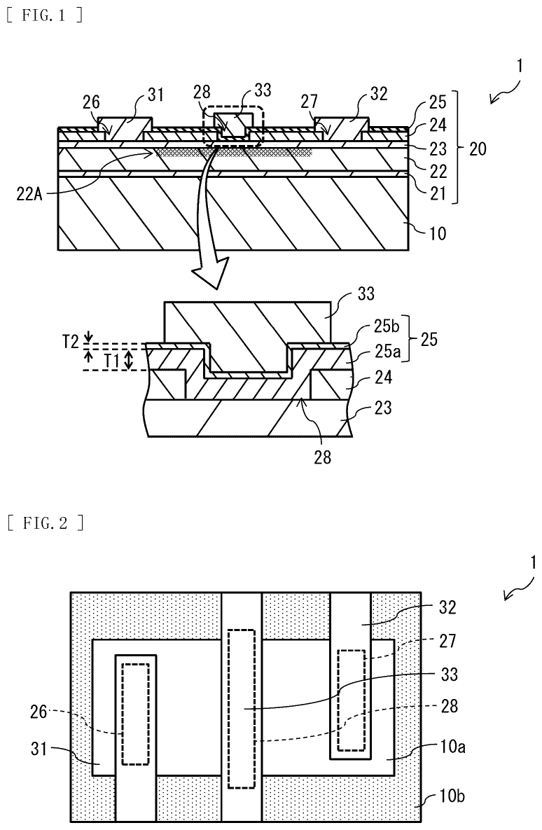

Description is given of a high electron mobility transistor (High Electron Mobility Transistor (HEMT)) according to an embodiment of the present technology. FIG. 1 illustrates a cross-sectional configuration example of a HEMT 1 according to the present embodiment. FIG. 2 illustrates a planar configuration example of the HEMT 1 of FIG. 1. The HEMT 1 has a so-called heterojunction structure in which a barrier layer 23 is stacked on a channel layer 22. In the HEMT 1, electrons accumulate at a high concentration in an area of the channel layer 22 adjacent to a heterojunction interface, and a so-called two-dimensional electron gas region 22A (two-dimensional electron gas (2DEG)) is formed. This two-dimensional electron gas region 22A exhibits high electron mobility. In particular, the barrier layer 23 stacked on the channel layer 22 induces an extremely high electron concentration on a surface of the channel layer 22.

As illustrated in FIG. 1, the HEMT 1 includes, for example, a semiconductor layer 20 on a substrate 10. The semiconductor layer 20 includes, for example, a buffer layer 21, the channel layer 22, and the barrier layer 23, in this order from a side adjacent to the substrate 10. The buffer layer 21 may be omitted as necessary.

The substrate 10 is, for example, a semi-insulating single-crystal GaN substrate. In the present embodiment, the buffer layer 21 is provided between the substrate 10 and the channel layer 22. Accordingly, the substrate 10 may be, for example, a SiC substrate, a sapphire substrate, a Si substrate, a SCAM substrate, a gallium oxide (Ga₂O₃) substrate, an AlN substrate, or a diamond substrate.

The buffer layer 21 is, for example, a compound semiconductor layer formed on the substrate 10 through epitaxial growth. In a case where the substrate 10 and the channel layer 22 have lattice constants different from each other, the lattice constants may be adjusted by the buffer layer 21 to thereby achieve a favorable crystal quality of the channel layer 22 and suppress a wafer warpage after formation of the channel layer 22. In a case where the substrate 10 is a Si substrate and the channel layer 22 includes GaN, the buffer layer 21 includes, for example, AlN, AlGaN, or GaN. It is to be noted that the buffer layer 21 is not necessarily a single layer, and may have a configuration in which at least two types of materials selected from, for example, AlN, AlGaN, and GaN are stacked. In a case where the buffer layer 21 includes a ternary material (e.g., AlGaN), the buffer layer 21 may have a configuration in which a composition of the ternary material gradually varies in its thickness direction. The buffer layer 21 may not necessarily be a compound semiconductor layer formed through epitaxial growth. For example, at least a portion of the buffer layer 21 in contact with the substrate 10 may be an incomplete epitaxial-crystal-growth layer formed due to an influence of uncertainty in a manufacturing process.

The channel layer 22 is, for example, a compound semiconductor layer formed on the substrate 10 or the buffer layer 21 through epitaxial growth. The channel layer 22 is provided at a location opposing at least a gate electrode 33 described later. The channel layer 22 includes a nitride semiconductor (e.g., GaN). When the HEMT 1 operates, the two-dimensional electron gas region 22A develops in the area of the channel layer 22 adjacent to the heterojunction interface to thereby form a channel region in the area of the channel layer 22 adjacent to the heterojunction interface. The channel region is a region that forms a portion of an electric current path between source-drain electrodes 31 and 32 and in which carriers accumulate due to a difference in an amount of polarization charge between the barrier layer 23 and the channel layer 22. The channel layer 22 may include a nitride semiconductor undoped with impurities (e.g., u-GaN undoped with impurities). In this case, diffusion of impurity carriers in the channel layer 22 is suppressed, which allows the carriers to move with high mobility.

The barrier layer 23 is, for example, a compound semiconductor layer formed on the channel layer 22 through epitaxial growth. The barrier layer 23 serves to accumulate carriers in the channel layer 22 by polarizing the barrier layer 23 and the channel layer 22. The barrier layer 23 includes a material that generates a difference in the amount of the polarization charge between the barrier layer 23 and the channel layer 22 to enable the carriers to accumulate at an interface between the barrier layer 23 and the channel layer 22. Examples of such a material include AlₓIn₁₋ₓN (0≤x<1) and Al_{1-x-y}InₓGa_{y}N (0≤x<1, 0≤y<1, x+y=1). The barrier layer 23 may include, for example, u-Al_{1-x-y}InₓGa_{y}N (0≤x<1, 0≤y<1, x+y=1) undoped with impurities. In this case, the diffusion of impurity carriers in the channel layer 22 is suppressed, which allows the carriers to move with high mobility.

As illustrated in FIG. 1, the HEMT 1 further includes, for example, an insulating layer 24 and a gate insulating film 25 on the semiconductor layer 20. The insulating layer 24 is provided to cover the barrier layer 23. The insulating layer 24 includes a material that has an insulating property with respect to the barrier layer 23 and the gate electrode 33 described later and does not lower a device property by protecting a surface of the barrier layer 23 from impurities such as ions and further forming a favorable interface between the insulating layer 24 and the barrier layer 23. The insulating layer 24 includes, for example, Al₂O₃, HfO₂, or SiO₂. The insulating layer 24 may have a configuration in which at least two materials out of, for example, Al₂O₃, HfO₂, and SiO₂ are stacked. As illustrated in FIG. 1, the insulating layer 24 has, for example, respective openings 26 and 27 for provision of the source-drain electrodes 31 and 32 and an opening 28 for provision of the gate electrode 33. The openings 26, 27, and 28 have bottom surfaces at which the surface of the barrier layer 23 is exposed. A cap layer may be provided between the insulating layer 24 and the barrier layer 23. The cap layer is a layer stacked on the barrier layer 23. The cap layer is, for example, a layer formed by stacking GaN or SiN on the barrier layer 23, or a layer formed by stacking GaN and SiN on the barrier layer 23.

The gate insulating film 25 is provided to cover an inner surface of the opening 28 and an upper surface of the insulating layer 24. In the opening 28, the gate insulating film 25 is provided between the barrier layer 23 and the gate electrode 33. The gate insulating film 25 is in contact with the surface, of the barrier layer 23, exposed at the bottom surface of the opening 28. As illustrated in the enlarged view in FIG. 1, the gate insulating film 25 includes, for example, a first insulating film 25a and a second insulating film 25b. The first insulating film 25a is in contact with the surface of the barrier layer 23. The second insulating film 25b is in contact with the first insulating film 25a and the gate electrode 33.

The first insulating film 25a and the second insulating film 25b satisfy relational expressions (1), (2), and (3) below.

$$EOT ( T 1 ) / EOT ( T 2 ) \geq 1.43 \qquad ( 1 )$$

$$EOT ( T 2 ) \leq 0.75 nm \qquad ( 2 )$$

$$ε 1 \geq ε 2 \qquad ( 3 )$$

where
T1: a thickness (nm) of the first insulating film 25a
T2: a thickness (nm) of the second insulating film 25b
EOT(T1): an equivalent oxide film thickness of the first insulating film 25a
EOT(T2): an equivalent oxide film thickness of the second insulating film 25b
ε1: a relative permittivity of the first insulating film 25a
ε2: a relative permittivity of the second insulating film 25b
EOT: an equivalent oxide film thickness (a film thickness equivalent to a film thickness of a silicon oxide film in terms of electrostatic capacitance)

The first insulating film 25a includes an insulating material including a group 4 metal element or a group 5 metal element. The second insulating film 25b includes an insulating material including a group 13 metal element, a group 14 metal element, a group 13 semiconductor element, or a group 14 semiconductor element. The first insulating film 25a and the second insulating film 25b each have a single-layer structure. The first insulating film 25a includes, for example, HfO₂, HfAlO, TiO₂, NbO, Nb₂O₅, or ZrO₂. The second insulating film 25b has a thickness of, for example, less than or equal to 1 nm, and includes, for example, Al₂O₃, GeO₂, SiO₂, or SiN. For example, the first insulating film 25a includes HfO₂ having a thickness of 6 nm, and the second insulating film 25b includes Al₂O₃ having a thickness of 1 nm. The first insulating film 25a and the second insulating film 25b are not limited to the above-described combination of materials. For example, the first insulating film 25a and the second insulating film 25b may include any of the following combinations of materials. The respective materials of the first insulating film 25a and the second insulating film 25b are not limited to the above-described materials.

| First Insulating Film 25a | Second Insulating Film 25b |
|---|---|
| HfO₂ | SiN |
| HfO₂ | SiO₂ |
| TiO₂ | Al₂O₃ |

At least one of the first insulating film 25a or the second insulating film 25b may be a graded layer having a composition that gradually varies in its thickness direction. Further, in the first insulating film 25a and the second insulating film 25b, interdiffusion of elements may occur at and in an area adjacent to an interface between the first insulating film 25a and the second insulating film 25b. Even in a case where the first insulating film 25a and the second insulating film 25b have such a configuration, the first insulating film 25a and the second insulating film 25b each have no interface therein and thus are each considered as substantially having a single-layer structure.

The first insulating film 25a and the second insulating film 25b may satisfy a relational expression (4) below. In a case where the first insulating film 25a and the second insulating film 25b satisfy a relational expression (5) below, the first insulating film 25a includes HfO₂ having a thickness of 8 nm and the second insulating film 25b includes Al₂O₃ having a thickness of 2 nm. In this case, the gate insulating film 25 has a total thickness of 10 nm, and the HEMT 1 exhibits a high-frequency property that is not so favorable as compared with a case where the gate insulating film 25 has a total thickness of less than 10 nm. Such a HEMT 1 is not so suitable for use as, for example, a power amplifier.

$$EOT ( T 1 ) + EOT ( T 2 ) < 2.3 nm \qquad ( 4 )$$

$$EOT ( T 1 ) + EOT ( T 2 ) = 2.3 nm \qquad ( 5 )$$

As illustrated in FIG. 1, the HEMT 1 further includes, for example, the source-drain electrode 31 in the opening 26 and the source-drain electrode 32 in the opening 27. As illustrated in FIG. 1, the HEMT 1 further includes, for example, the gate electrode 33 in the opening 28. The source-drain electrodes 31 and 32 are in ohmic contact with the barrier layer 23 (the semiconductor layer 20) via the openings 26 and 27, respectively. The gate electrode 33 is in contact with the gate insulating film 25 in the opening 28. The source-drain electrodes 31 and 32 each include, for example, a Ti/Al/Ni/Au stack body. The gate electrode 33 includes, for example, a Ni/Au stack body.

As illustrated in FIG. 2, for example, the HEMT 1 is formed in an active region 10a of the semiconductor layer 20. As illustrated in FIG. 2, for example, the semiconductor layer 20 includes an element separation region 10b around the active region 10a. The element separation region 10b is increased in resistance by implanting ions such as boron. Accordingly, the active region 10a is island-shaped in the semiconductor layer 20.

### <Manufacturing Method>

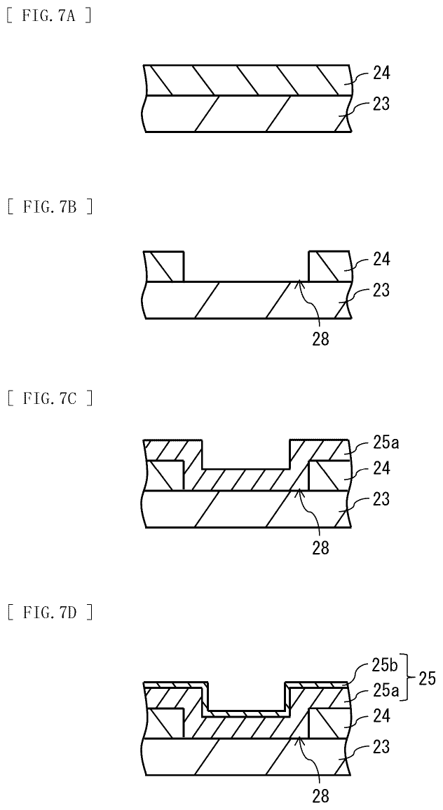

Next, description is given of a manufacturing method of the HEMT 1 according to the present embodiment. FIGS. 7A to 7D are each an explanatory diagram of a manufacturing step of the HEMT 1 according to the present embodiment.

First, the semiconductor layer 20 is formed on the substrate 10. For example, the semiconductor layer 20 is formed on the substrate 10 through epitaxial growth. Thereafter, the unillustrated element separation region 10b and an unillustrated source-drain region are formed in the semiconductor layer 20. For example, selective regrowth or ion implantation may be used to form the source-drain region. Thereafter, the insulating layer 24 is formed to cover a surface of the semiconductor layer 20 (FIG. 7A). For example, an atomic layer deposition (ALD) method or a chemical vapor deposition (CVD) method is used to stack Al₂O₃ or SiO₂ to cover the surface of the semiconductor layer 20. In this way, the insulating layer 24 is formed on the semiconductor layer 20.

Thereafter, the insulating layer 24 is subjected to pattern etching to thereby form the unillustrated openings 26 and 27 and the opening 28 (FIG. 7B). In the openings 26, 27, and 28, the surface of the barrier layer 23 is exposed. Here, dry etching is preferably used to prevent the openings 26, 27, and 28 from being widened. Dry etching and wet etching may be combined to reduce damage to the barrier layer 23. For example, dry etching may be used until a small amount of the insulating layer 24 is left at the bottom surfaces of the openings 26, 27, and 28, and thereafter wet etching may be used until the surface of the barrier layer 23 is exposed at the bottom surfaces of the openings 26, 27, and 28. Further, the openings 26, 27, and 28 are not necessarily formed simultaneously. For example, the formation of the openings 26 and 27 and the formation of the opening 28 may be performed by different processes.

Thereafter, the first insulating film 25a is formed to cover inner surfaces of the unillustrated openings 26 and 27, the inner surface of the opening 28, and the surface of the barrier layer 23 (FIG. 7C). For example, the first insulating film 25a is formed by forming an about 6-nm-thick film of HfO₂ by the ALD method. Thereafter, the second insulating film 25b is formed to cover a surface of the first insulating film 25a (FIG. 7D). For example, the second insulating film 25b is formed by forming an about 1-nm-thick film of Al₂O₃ by the ALD method. Thereafter, the source-drain electrodes 31 and 32 and the gate electrode 33 are formed. For example, the source-drain electrodes 31 and 32 and the gate electrode 33 are formed by forming films of Ti, Al, Ni, and Au in this order by a vapor deposition method. In this way, the HEMT 1 is manufactured.

### Effects

Next, description is given of effects of the HEMT 1 according to the present embodiment in comparison with a comparative example.

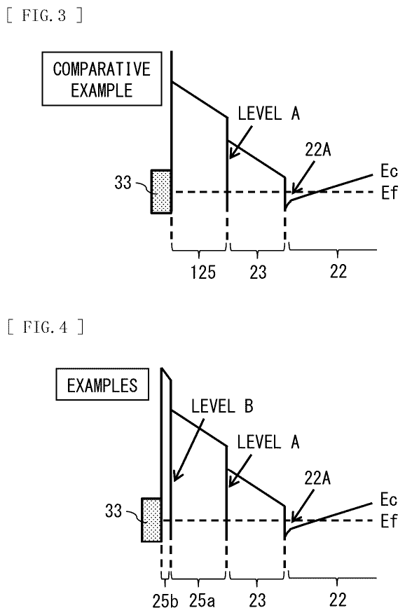

FIG. 3 illustrates an example of an energy band of a HEMT of the comparative example. In the comparative example, a threshold voltage variation due to stress during operation is mainly caused by injecting electric charge from the gate electrode 33 into a level A present at an interface between a single-layer gate insulating film 125 and the barrier layer 23. Provided that a film thickness of the gate insulating film 125 is T, a relative permittivity of the gate insulating film 125 is er, and the electric charge trapped at the level A is ΔQ, the resulting threshold voltage variation is ΔVth∝(T/εr)×ΔQ.

On the basis of this relational expression, three possible techniques to suppress the threshold voltage variation are conceivable.
(1) Decrease the film thickness T of the gate insulating film 125.
(2) Increase the relative permittivity er of the gate insulating film 125.
(3) Reduce the injection of the electric charge into the level A.

In the technique (1), if the gate insulating film 125 is thin, a gate leakage is increased and a withstand voltage of the transistor is lowered. It is thus difficult to adopt the technique (1). The technique (2) necessitates changing a material of the gate insulating film 125. However, the change in the material of the gate insulating film 125 is difficult. It is thus difficult to adopt the technique (2). In view of the above, the inventor of the present application has aimed at suppressing the threshold voltage variation by the technique (3).

FIG. 4 illustrates an example of an energy band of HEMTs of examples. In the examples, the gate insulating film 125 includes a stack body of the first insulating film 25a and the second insulating film 25b. This creates a level B at the interface between the first insulating film 25a and the second insulating film 25b. A portion of the electric charge injected from the gate electrode 33 under stress is thus trapped at the level B. As a result, the electric charge trapped at the level B is not to be injected into the level A. This makes it possible to reduce the injection of the electric charge into the level A and thus reduce the threshold voltage variation. Further, a distance from the gate electrode 33 to the level B may be shortened by making a film thickness of the second insulating film 25b smaller than that of the first insulating film 25a. As a result, it is possible to reduce the influence of the threshold voltage variation caused by the electric charge trapped at the level B. Furthermore, it is possible to minimize occurrence of a decrease in a gain caused by a reduction in gate capacitance, by making the film thickness of the second insulating film 25b smaller than that of the first insulating film 25a. It is to be noted that, in a case where the gate insulating film 125 includes a single layer of HfO₂, a material having a high permittivity is used for the gate insulating film 125, as in the technique (2). This, however, fails to sufficiently reduce an amount of the threshold voltage variation because an amount of the electric charge injected into the level A becomes larger than that in a case where the gate insulating film 125 has a stacked structure. In view of this as well, it is found that a stacked structure of the gate insulating film 125 is important to reduce the influence of the threshold voltage variation.

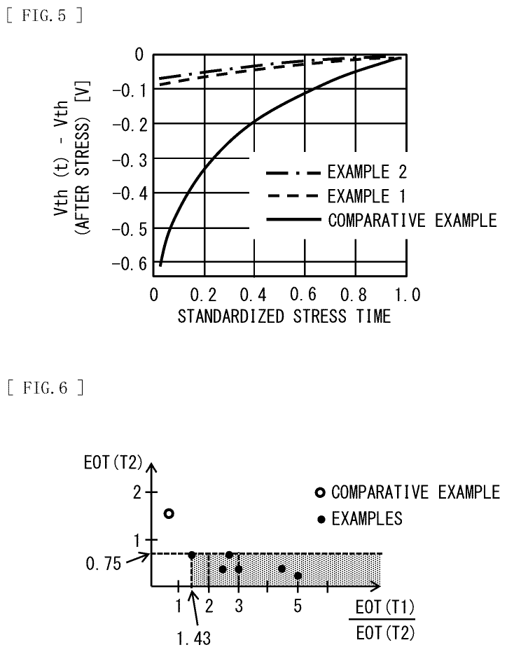

Next, an effect of improving the threshold voltage variation in the examples was verified by an experiment. FIG. 5 illustrates an example of the threshold voltage variation when stress is applied to the HEMTs of the examples and the HEMT of the comparative example. FIG. 6 illustrates conditions determined for the gate insulating film 25 on the basis of the results of FIG. 5. In the verification of FIG. 5, a bias that caused an electric current of 50 mA/mm to flow was applied as stress to the HEMTs. Further, in FIG. 5, the vertical axis indicates a value resulting from subtracting a threshold voltage after stress at each time from a threshold voltage at each time. A reason for this is to eliminate an influence of a difference in the threshold voltage generated depending on a film configuration. The horizontal axis indicates a standardized stress time.

In the comparative example of FIG. 5, a material having a relative permittivity of 20 was used for the first insulating film 25a, a material having a relative permittivity of 10 was used for the second insulating film 25b, EOT(T1)/EOT(T2)=0.75 was satisfied, and EOT(T2) of the second insulating film 25b was 1.56. In Examples 1 and 2 of FIG. 5, a material (HfO₂) having a relative permittivity of 20 was used for the first insulating film 25a, and a material (Al₂O₃) having a relative permittivity of 10 was used for the second insulating film 25b. In Example 1 of FIG. 5, EOT(T1)/EOT(T2)=3 was satisfied, and EOT(T2) of the second insulating film 25b was 0.39. In Example 2 of FIG. 5, EOT(T1)/EOT(T2)=5 was satisfied, and EOT(T2) of the second insulating film 25b was 0.234.

In the comparative example of FIG. 5, a threshold voltage variation of about 0.6 V occurs under stress, whereas in Examples 1 and 2 of FIG. 5, only a variation of less than 0.1 V occurs and the amount of the threshold voltage variation is about one sixth of that of the comparative example. A power amplifier for a mobile terminal demands an amount of the threshold voltage variation of, for example, less than 0.1 V. This demand is thus satisfiable by the amounts of the variation in Examples 1 and 2 of FIG. 5.

One reason why a material having a high permittivity is used for the first insulating film 25a is that the first insulating film 25a is thicker than the second insulating film 25b. In Examples 1 and 2 of FIG. 5, T1>T2 is satisfied. If a material having a low permittivity is used for the first insulating film 25a, the material having a low permittivity is used for a large portion of the gate insulating film 25, which leads to a decrease in the gain. Accordingly, it is necessary for the first insulating film 25a to have a higher relative permittivity than the second insulating film 25b.

Further, it is found from the results of the experiment in Examples 1 and 2 of FIG. 5 that the threshold voltage variation under stress is made less than or equal to 0.1 V by forming the first insulating film 25a with HfO₂ having a thickness of 6 nm and forming the second insulating film 25b with Al₂O₃ having a thickness of 1 nm. In this case, the first insulating film 25a and the second insulating film 25b satisfy a relational expression (6) below.

$$EOT ( T 1 ) / EOT ( T 2 ) \geq 3 \qquad ( 6 )$$

Meanwhile, according to the above-described PTL 1 and the like, it is found that relative permittivities of HfO₂ and Al₂O₃ are each in a certain range. When the relational expression (6) is redefined in consideration of certain margins for the ranges of the relative permittivities, the relational expression (1) is given.

Further, when the EOT of the second insulating film 25b is also calculated provided that Al₂O₃ is set to a typical relative permittivity of 10 and the film thickness of the second insulating film 25b is set to 1 nm, the second insulating film 25b satisfies a relational expression (7) below. Meanwhile, in consideration of the range of the relative permittivity of Al₂O₃ and use of a material having a lower permittivity than Al₂O₃ for the second insulating film 25b, the relational expression (2) described above is given.

$$EOT ( T 2 ) \leq 0.39 nm \qquad ( 7 )$$

Furthermore, in the examples, possible combinations of the first insulating film 25a and the second insulating film 25b are set. When calculated in the respective examples, EOT(T1)/EOT(T2) and EOT(T2) have values plotted in FIG. 6. In the five examples of FIG. 6, the first insulating film 25a and the second insulating film 25b satisfy a relational expression (8) below.

$$EOT ( T 1 ) / EOT ( T 2 ) \geq 2 \qquad ( 8 )$$

As described above, in the present embodiment, it is possible to achieve the HEMT 1 having an excellent operating property by forming the first insulating film 25a and the second insulating film 25b that satisfy the above-described conditions.

### 3. MODIFICATION EXAMPLES

Next, description is given of modification examples of the HEMT 1 according to the foregoing embodiment. Hereinbelow, common reference numerals are assigned to common components, and description of the common components is omitted as appropriate.

### Modification Example A

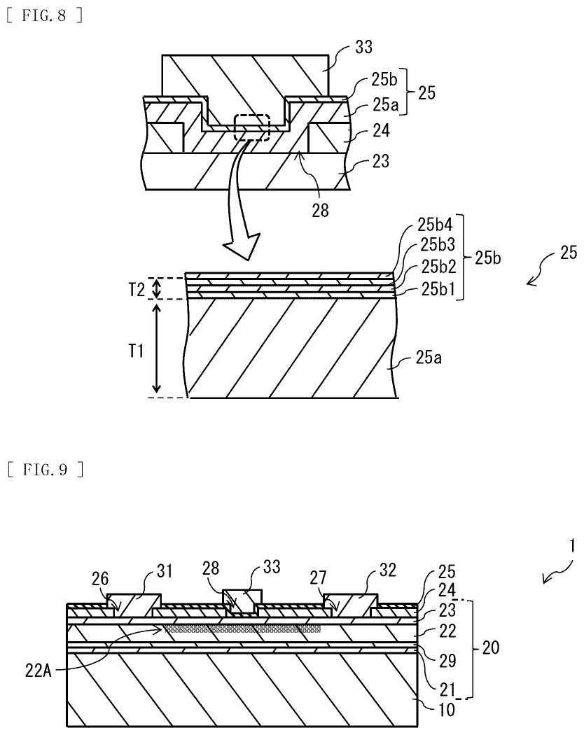

In the foregoing embodiment, the second insulating film 25b may have a multilayer structure in which films in contact with each other have relative permittivities different from each other. In the present modification example, as illustrated in FIG. 8, the second insulating film 25b has, for example, a configuration in which an insulating film 25b1, an insulating film 25b2, an insulating film 25b3, and an insulating film 25b4 are stacked in this order from a side adjacent to the first insulating film 25a. In this case, a total thickness of the insulating film 25b1, the insulating film 25b2, the insulating film 25b3, and the insulating film 25b4 is T2. The insulating layers 25b1 and 25b3 each include, for example, Al₂O₃. The insulating layers 25b2 and 25b4 each include, for example, SiO₂. It is to be noted that the number of films included in the second insulating film 25b is not limited to four, and may be two or three, or may be five or more.

In the present modification example, the second insulating film 25b has a multilayer structure. This causes most of the electric charge injected from the gate electrode 33 to be trapped at an interface closest to the gate electrode 33 out of a plurality of interfaces included in the second insulating film 25b. As a result, it is possible to reduce the influence of the threshold voltage variation caused by the electric charge trapped at the level B. Further, it is possible to minimize the occurrence of a decrease in the gain caused by a reduction in the gate capacitance.

### Modification Example B

In the foregoing embodiment and the modification example thereof, as illustrated in FIG. 9, for example, a back barrier layer 29 may be provided between the buffer layer 21 and the channel layer 22. The back barrier layer 29 is a compound semiconductor layer formed on the buffer layer 21 through epitaxial growth. The back barrier layer 29 includes a compound semiconductor material that raises an energy band of an area of the channel layer 22 close to the back barrier layer 29. The back barrier layer 29 includes, for example, AlₓGa_{y}InₓN (x+y+z=1, x≥0, y≥0, z≥0). The back barrier layer 29 may include, for example, u-AlₓGa_{y}InₓN undoped with impurities. As described above, it is possible to achieve the HEMT 1 having an excellent operating property by providing the back barrier layer 29 between the buffer layer 21 and the channel layer 22.

### Modification Example C

In the foregoing embodiment and the modification examples thereof, the present technology is applied to the HEMT. However, the present technology is certainly applicable to a FET in the foregoing embodiment and the modification examples thereof. That is, in the foregoing embodiment and the modification examples thereof, the FET may be used in place of the HEMT 1.

### Modification Example D

In the foregoing embodiment and the modification examples thereof, the second insulating film 25b may have a thickness of, for example, 1 nm or greater and less than 2 nm. In this case, it is possible to enhance a dielectric withstand voltage of a device while suppressing the threshold voltage variation.

### 4. APPLICATION EXAMPLES

Next, description is given of application examples of the HEMT 1 according to any of the foregoing embodiment and the modification examples thereof. Hereinbelow, common reference numerals are assigned to common components, and description of the common components is omitted as appropriate.

### Application Example α

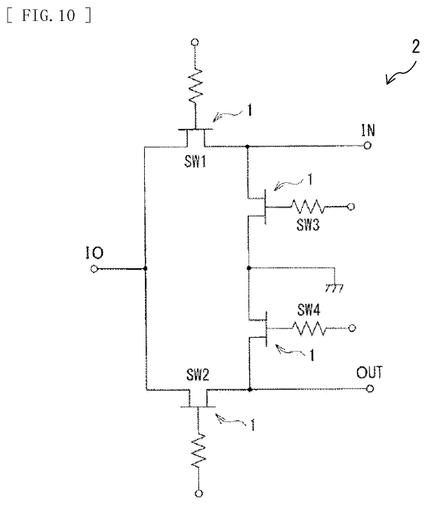

FIG. 10 illustrates an example of an RF switch circuit 2. The RF switch circuit 2 is used in a mobile communication system for a mobile phone, for example. The RF switch circuit 2 includes, for example, a first terminal IN, a second terminal IO, a third terminal OUT, a first switching device SW1, and a second switching device SW2.

A transmitted signal is inputted to the first terminal IN. The second terminal IO is coupled to an antenna. The third terminal OUT outputs a received signal received by the antenna. The first switching device SW1 is coupled between the first terminal IN and the second terminal IO. The second switching device SW2 is coupled between the second terminal IO and the third terminal OUT. One or both of the first switching device SW1 and the second switching device SW2 include the HEMT 1 according to any of the foregoing embodiment and the modification examples thereof.

A third switching device SW3 is coupled between the first terminal IN and a power supply (a ground in this example). A fourth switching device SW4 is coupled between the third terminal OUT and the power supply (the ground in this example). One or both of the third switching device SW3 and the fourth switching device SW4 include the HEMT 1 according to any of the foregoing embodiment and the modification examples thereof.

In the RF switch circuit 2, in a case of transmission, that is, in a case where a transmitted signal is outputted from a transmission system of a wireless communication apparatus to the antenna, the first switching device SW1 and the fourth switching device SW4 are brought into a conducting state, and the second switching device SW2 and the third switching device SW3 are brought into a non-conducting state. In this case, the transmitted signal is inputted from the first terminal IN and outputted to the second terminal IO via the first switching device SW1.

In a case of reception, that is, in a case where a signal received by the antenna is inputted to a reception system of the wireless communication apparatus, the first switching device SW1 and the fourth switching device SW4 are brought into the non-conducting state, and the second switching device SW2 and the third switching device SW3 are brought into the conducting state. In this case, the received signal received by the antenna is inputted from the second terminal IO and outputted to the third terminal OUT via the second switching device SW2.

As described above, in the present application example, the HEMT 1 according to any of the foregoing embodiment and the modification examples thereof is used. This enables enhancement of electric power efficiency.

### Application Example β

FIG. 11 illustrates an example of a wireless communication terminal 3. The wireless communication terminal 3 is, for example, a multifunctional mobile phone system for audio or data communication or LAN connection. The wireless communication terminal 3 includes, for example, an antenna ANT, the RF switch circuit 2, a high-power amplifier HPA, a radio frequency integrated circuit RFIC (a Radio Frequency Integrated Circuit), a baseband unit BB, an audio output unit MIC, a data output unit DT, and an interface I/F (e.g., a wireless LAN (Wireless Local Area Network or W-LAN) or Bluetooth (registered trademark)). The RF switch circuit 2 has, for example, the configuration illustrated in FIG. 10. The radio frequency integrated circuit RFIC and the baseband unit BB are coupled to each other by the interface I/F.

In the wireless communication terminal 3, in a case of transmission, that is, in a case where a transmitted signal is outputted from a transmission system of the wireless communication terminal 3 to the antenna ANT, a transmitted signal outputted from the baseband unit BB is outputted to the antenna ANT via the radio frequency integrated circuit RFIC, the high-power amplifier HPA, and the RF switch circuit 2.

In a case of reception, that is, in a case where a signal received by the antenna ANT is inputted to a reception system of the wireless communication terminal 3, the received signal is inputted to the baseband unit BB via the RF switch circuit 2 and the radio frequency integrated circuit RFIC. The signal processed by the baseband unit BB is outputted from an output unit such as the audio output unit MIC, the data output unit DT, or the interface I/F.

As described above, in the present application example, the HEMT 1 according to any of the foregoing embodiment and the modification examples thereof is used. This enables the enhancement of the electric power efficiency.

### Application Example γ

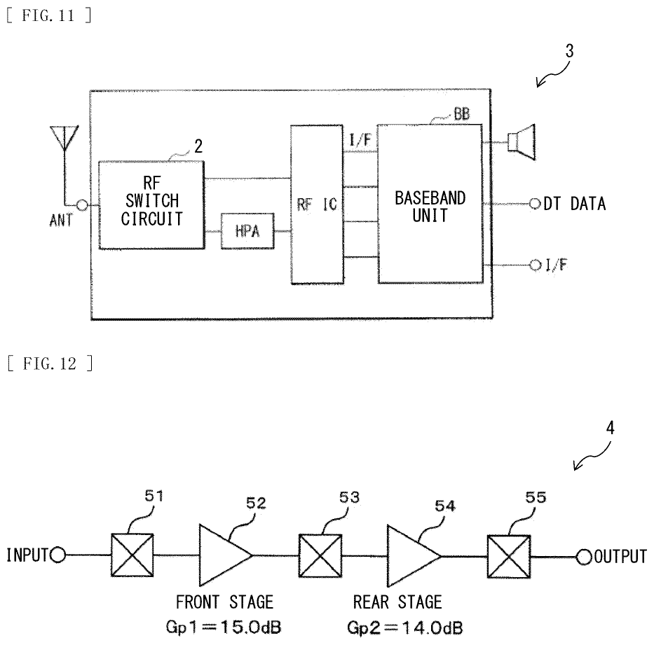

FIG. 12 illustrates an example of a power amplifier module 4. In the power amplifier module 4, power amplifiers each including the HEMT 1 according to any of the foregoing embodiment and the modification examples thereof are coupled in multiple stages on the same substrate. FIG. 12 illustrates a circuit configuration of the power amplifier module 4 in compliance with W-CDMA specification requirements.

As illustrated in FIG. 12, the power amplifier module 4 includes an input matching circuit 51, a front-stage power amplifier 52, a middle matching circuit 53, a rear-stage power amplifier 54, and an output matching circuit 55. Further, a gain of the front-stage power amplifier 52 is set to 15.0 dB, and a gain of the rear-stage power amplifier 54 is set to 14.0 dB.

Further, the front-stage power amplifier 52 and the rear-stage power amplifier 54 each include, as an amplifying device, the HEMT 1 according to any of the foregoing embodiment and the modification examples thereof.

As described above, in the present application example, the HEMT 1 according to any of the foregoing embodiment and the modification examples thereof is used. This enables the enhancement of the electric power efficiency.

Although the present technology has been described above with reference to the embodiment, the modification examples, and the application examples, the present technology is not limited to the foregoing embodiment and the like, and various modifications are possible. It is to be noted that the effects described herein are merely exemplary. Effects of the present technology are not limited to the effects described herein. The present technology may have effects other than the effects described herein.

For example, in the foregoing embodiment and the like, the semiconductor layer 20 mainly includes a GaN semiconductor; however, the semiconductor layer 20 may mainly include a group III-V semiconductor or a group II-VI semiconductor. For example, the semiconductor layer 20 may mainly include a GaAs semiconductor.

For example, the present technology may also have the following configurations.

(1)

A high electron mobility transistor including:
a semiconductor layer;
a gate electrode; and
a gate insulating film provided between the semiconductor layer and the gate electrode, in which
the gate insulating film includes
   a first insulating film in contact with the semiconductor layer, and
   a second insulating film in contact with the first insulating film and the gate electrode, and
the first insulating film and the second insulating film satisfy relational expressions (A), (B), and (C) below,

$$EOT ( T 1 ) / EOT ( T 2 ) \geq 1.43 \qquad ( A )$$

$$EOT ( T 2 ) \leq 0.75 nm \qquad ( B )$$

$$ε1 \geq ε 2 \qquad ( C )$$

where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance.
   (2)

The high electron mobility transistor according to (1), in which the first insulating film and the second insulating film each have a single-layer structure.

(3)

The high electron mobility transistor according to (1), in which
the first insulating film has a single-layer structure, and
the second insulating film has a multilayer structure in which films in contact with each other have relative permittivities different from each other.
   (4)

The high electron mobility transistor according to any one of (1) to (3), in which the first insulating film and the second insulating film satisfy a relational expression (D) below,

$$EOT ( T 1 ) + EOT ( T 2 ) < 2.3 nm . \qquad ( D )$$

(5)

The high electron mobility transistor according to any one of (1) to (4), in which the second insulating film has a film thickness of less than or equal to 1 nm.

(6)

The high electron mobility transistor according to any one of (1) to (4), in which the second insulating film has a film thickness of 1 nm or greater and less than 2 nm.

(7)

The high electron mobility transistor according to any one of (1) to (6), in which
the first insulating film includes a group 4 metal element or a group 5 metal element, and
the second insulating film includes a group 13 metal element, a group 14 metal element, a group 13 semiconductor element, or a group 14 semiconductor element.
   (8)

The high electron mobility transistor according to any one of (1) to (7), in which the semiconductor layer includes a channel layer at a location opposing at least the gate electrode, the channel layer including a nitride semiconductor.

(9)

The high electron mobility transistor according to (8), in which the semiconductor layer includes a barrier layer between the gate insulating film and the channel layer, the barrier layer including AlₓIn₁₋ₓN, where 0≤x<1 is satisfied, or Al_{1-x-y}InₓGa_{y}N, where 0≤x<1, 0≤y<1, and x+y=1 are satisfied.

(10)

The high electron mobility transistor according to (9), in which the semiconductor layer includes a back barrier layer at a location opposing the barrier layer with the channel layer provided therebetween, the back barrier layer including AlₓGa_{y}InₓN, where x+y+z=1, x≥0, y≥0, and z≥0 are satisfied.

(11)

The high electron mobility transistor according to any one of (1) to (10), in which the first insulating film and the second insulating film satisfy a relational expression (E) below,

$$EOT ( T 1 ) / EOT ( T 2 ) \geq 2 . \qquad ( E )$$

(12)

The high electron mobility transistor according to any one of (1) to (10), in which the first insulating film and the second insulating film satisfy a relational expression (F) below,

$$EOT ( T 1 ) / EOT ( T 2 ) \geq 3 . \qquad ( F )$$

(13)

An RF switch circuit including a high electron mobility transistor, in which
the high electron mobility transistor includes
   a semiconductor layer,
   a gate electrode, and
   a gate insulating film provided between the semiconductor layer and the gate electrode,
the gate insulating film includes
   a first insulating film in contact with the semiconductor layer, and
   a second insulating film in contact with the first insulating film and the gate electrode, and
the first insulating film and the second insulating film satisfy relational expressions (A), (B), and (C) below,

$$EOT ( T 1 ) / EOT ( T 2 ) \geq 1.43 \qquad ( A )$$

$$EOT ( T 2 ) \leq 0.75 nm \qquad ( B )$$

$$ε1 \geq ε 2 \qquad ( C )$$

where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance.
   (14)

A power amplifier circuit including a high electron mobility transistor, in which
the high electron mobility transistor includes
   a semiconductor layer,
   a gate electrode, and
   a gate insulating film provided between the semiconductor layer and the gate electrode,
the gate insulating film includes
   a first insulating film in contact with the semiconductor layer, and
   a second insulating film in contact with the first insulating film and the gate electrode, and
the first insulating film and the second insulating film satisfy relational expressions (A), (B), and (C) below,

$$EOT ( T 1 ) / EOT ( T 2 ) \geq 1.43 \qquad ( A )$$

$$EOT ( T 2 ) \leq 0.75 nm \qquad ( B )$$

$$ε1 \geq ε 2 \qquad ( C )$$

where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance.
   (15)

A wireless communication terminal including a high electron mobility transistor, in which
the high electron mobility transistor includes
   a semiconductor layer,
   a gate electrode, and
   a gate insulating film provided between the semiconductor layer and the gate electrode,
the gate insulating film includes
   a first insulating film in contact with the semiconductor layer, and
   a second insulating film in contact with the first insulating film and the gate electrode, and
the first insulating film and the second insulating film satisfy relational expressions (A), (B), and (C) below,

$$EOT ( T 1 ) / EOT ( T 2 ) \geq 1.43 \qquad ( A )$$

$$EOT ( T 2 ) \leq 0.75 nm \qquad ( B )$$

$$ε1 \geq ε 2 \qquad ( C )$$

where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance.

The present application claims the benefit of Japanese Priority Patent Application JP2023-106351 filed with the Japan Patent Office on Jun. 28, 2023, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A high electron mobility transistor comprising:
a semiconductor layer;
a gate electrode; and
a gate insulating film provided between the semiconductor layer and the gate electrode, wherein
the gate insulating film includes
a first insulating film in contact with the semiconductor layer, and
a second insulating film in contact with the first insulating film and the gate electrode, and
the first insulating film and the second insulating film satisfy relational expressions (A), (B), and (C) below,
$$EOT ( T 1 ) / EOT ( T 2 ) \geq 1.43 \qquad ( A )$$
$$EOT ( T 2 ) \leq 0.75 nm \qquad ( B )$$
$$ε1 \geq ε 2 \qquad ( C )$$
where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance.

2. The high electron mobility transistor according to claim 1, wherein the first insulating film and the second insulating film each have a single-layer structure.

3. The high electron mobility transistor according to claim 1, wherein
the first insulating film has a single-layer structure, and
the second insulating film has a multilayer structure in which films in contact with each other have relative permittivities different from each other.

4. The high electron mobility transistor according to claim 1, wherein the first insulating film and the second insulating film satisfy a relational expression (D) below,
$$EOT ( T 1 ) + EOT ( T 2 ) < 2.3 nm . \qquad ( D )$$

5. The high electron mobility transistor according to claim 1, wherein the second insulating film has a film thickness of less than or equal to 1 nm.

6. The high electron mobility transistor according to claim 1, wherein the second insulating film has a film thickness of 1 nm or greater and less than 2 nm.

7. The high electron mobility transistor according to claim 1, wherein
the first insulating film includes a group 4 metal element or a group 5 metal element, and
the second insulating film includes a group 13 metal element, a group 14 metal element, a group 13 semiconductor element, or a group 14 semiconductor element.

8. The high electron mobility transistor according to claim 1, wherein the semiconductor layer includes a channel layer at a location opposing at least the gate electrode, the channel layer including a nitride semiconductor.

9. The high electron mobility transistor according to claim 8, wherein the semiconductor layer includes a barrier layer between the gate insulating film and the channel layer, the barrier layer including AlₓIn₁₋ₓN, where 0≤x<1 is satisfied, or Al_{1-x-y}InₓGa_{y}N, where 0≤x<1, 0≤y<1, and x+y=1 are satisfied.

10. The high electron mobility transistor according to claim 9, wherein the semiconductor layer includes a back barrier layer at a location opposing the barrier layer with the channel layer provided therebetween, the back barrier layer including AlₓGa_{y}InₓN, where x+y+z=1, x≥0, y≥0, and z≥0 are satisfied.

11. The high electron mobility transistor according to claim 1, wherein the first insulating film and the second insulating film satisfy a relational expression (E) below,
$$EOT ( T 1 ) / EOT ( T 2 ) \geq 2 . \qquad ( E )$$

12. The high electron mobility transistor according to claim 1, wherein the first insulating film and the second insulating film satisfy a relational expression (F) below,
$$EOT ( T 1 ) / EOT ( T 2 ) \geq 3 . \qquad ( F )$$

13. An RF switch circuit comprising a high electron mobility transistor, wherein
the high electron mobility transistor includes
a semiconductor layer,
a gate electrode, and
a gate insulating film provided between the semiconductor layer and the gate electrode,
the gate insulating film includes
a first insulating film in contact with the semiconductor layer, and
a second insulating film in contact with the first insulating film and the gate electrode, and
the first insulating film and the second insulating film satisfy relational expressions (A), (B), and (C) below,
$$EOT ( T 1 ) / EOT ( T 2 ) \geq 1.43 \qquad ( A )$$
$$EOT ( T 2 ) \leq 0.75 nm \qquad ( B )$$
$$ε1 \geq ε 2 \qquad ( C )$$
where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance.

14. A power amplifier circuit comprising a high electron mobility transistor, wherein
the high electron mobility transistor includes
a semiconductor layer,
a gate electrode, and
a gate insulating film provided between the semiconductor layer and the gate electrode,
the gate insulating film includes
a first insulating film in contact with the semiconductor layer, and
a second insulating film in contact with the first insulating film and the gate electrode, and
the first insulating film and the second insulating film satisfy relational expressions (A), (B), and (C) below,
$$EOT ( T 1 ) / EOT ( T 2 ) \geq 1.43 \qquad ( A )$$
$$EOT ( T 2 ) \leq 0.75 nm \qquad ( B )$$
$$ε1 \geq ε 2 \qquad ( C )$$
where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance.

15. A wireless communication terminal comprising a high electron mobility transistor, wherein
the high electron mobility transistor includes
a semiconductor layer,
a gate electrode, and
a gate insulating film provided between the semiconductor layer and the gate electrode,
the gate insulating film includes
a first insulating film in contact with the semiconductor layer, and
a second insulating film in contact with the first insulating film and the gate electrode, and
the first insulating film and the second insulating film satisfy relational expressions (A), (B), and (C) below,
$$EOT ( T 1 ) / EOT ( T 2 ) \geq 1.43 \qquad ( A )$$
$$EOT ( T 2 ) \leq 0.75 nm \qquad ( B )$$
$$ε1 \geq ε 2 \qquad ( C )$$
where
T1: a thickness (nm) of the first insulating film
T2: a thickness (nm) of the second insulating film
EOT(T1): an equivalent oxide film thickness of the first insulating film
EOT(T2): an equivalent oxide film thickness of the second insulating film
ε1: a relative permittivity of the first insulating film
ε2: a relative permittivity of the second insulating film
EOT: an equivalent oxide film thickness indicating a film thickness equivalent to a film thickness of a silicon oxide film in terms of electrostatic capacitance.
